(19) United States
(12) Patent Application Publication
(10) Pub. No.: US 2024/0159849 A1
(43) Pub. Date: May 16, 2024

(54) GROUP INFORMATION GUIDED SMOOTH INDEPENDENT COMPONENT ANALYSIS METHOD FOR BRAIN FUNCTIONAL NETWORK ANALYSIS

(71) Applicant: SHANXI UNIVERSITY, Taiyuan (CN)

(72) Inventor: Yuhui DU, Taiyuan (CN)

(21) Appl. No.: 18/387,862

(22) Filed: Nov. 8, 2023

(30) Foreign Application Priority Data
Nov. 8, 2022 (CN) 202211393732.2

(51) Int. Cl. G01R 33/56; G06V 10/32; G06V 10/77

(52) U.S. Cl. CPC G01R 33/5608; G06V 10/32; G06V 10/7715; G06V 2201/031

(57) ABSTRACT

A group information guided smooth independent component analysis method for brain functional network analysis is provided. The method includes: performing independent component analysis on multi-subject fMRI data to obtain independent components at the group level; constructing multi-objective function that reflects independence of component of individual subject, correspondence of component across different subjects, and spatial smoothness of component based on iterative reference component that are initialized using group-level independent component, iterative voxel-level features that are computed based on reference component, and individual subject's fMRI data; iteratively optimizing multi-objective function to estimate independent components; and obtaining brain functional networks and calculating time courses of brain functional networks for individual subject.

### CROSS-REFERENCE TO RELATED APPLICATIONS

This application claims priority to Chinese patent application No. 202211393732.2, filed on Nov. 8, 2022, the content of which is hereby incorporated by reference in its entirety.

### TECHNICAL FIELD

The present disclosure generally relates to the field of brain image independent component analysis, and in particular, to a group information guided smooth independent component analysis method for brain functional network analysis.

### BACKGROUND

Analyzing brain functional networks (FNs) is crucial for understanding brain function. FNs not only deepen knowledge of human cognitive functions but also help identify stable biomarkers to predict brain disorders. Independent component analysis (ICA) is a widely used data-driven method for analyzing brain FNs from functional magnetic resonance imaging (fMRI) data. However, applying ICA directly to fMRI data of an individual subject is challenging, as resulting components (including meaningful FNs) are randomly ordered, thus resulting in different orders of components for different subjects. However, FN comparability or correspondence is a must for further mining FN-related biomarkers by comparing or distinguishing different groups, as well as predicting disorder situation of new subjects by using FNs.

Group ICA methods such as dual regression, group information guided ICA (GIG-ICA) and so on, have been developed to analyze FNs from multi-subject fMRI data. These methods first compute group-level components and then estimate individual-level components. However, none of these methods can guarantee smoothness of individual-level FNs, especially when faced with challenges of low signal-to-noise ratios in fMRI data affected by intricate noise. The extraction of more precise and less noisy brain FNs is greatly needed for understanding brain function, revealing mechanisms of brain disorders, and accurate diagnosis of brain disorders.

### SUMMARY

To address the limitation of these group ICA methods that does not optimize the smoothness of extracted FNs, the present disclosure provides a new group information guided smooth independent component analysis (GIG-sICA) method to effectively achieve smooth FNs that are less affected by noises while still being able to guarantee accuracy and correspondence of FNs.

In order to achieve the above purpose, the present disclosure adopts following technical schemes.

The group information guided smooth independent component analysis method for brain functional network analysis includes step 1 to step 9,
step 1 includes preprocessing functional magnetic resonance imaging (fMRI) data of each subject and representing four-dimensional data as a two-dimensional matrix;
step 2 includes performing dimension reduction on data of two-dimensional matrices of all subjects at both a subject level and a group level in sequence along a temporal direction by using principal component analysis (PCA);
step 3 includes performing independent component analysis (ICA) on dimension-reduced data to obtain group-level independent components (ICs) and identify FN-related group-level ICs;
step 4 includes calculating 13 voxel-level features for each voxel based on each reference component that is initialized by using each FN-related group-level IC;
step 5 includes constructing a multi-objective function by employing the voxel-level features of each component, each reference component, and an individual subject's data matrix, and then normalizing the multi-objective function;
step 6 includes iteratively optimizing the multi-objective function, if termination condition is not met, updating the reference component and then performing step 4 to step 5 again;
step 7 includes outputting an IC that represents a FN for the individual subject;
step 8 includes calculating time course of the FN for the individual subject;
step 9 includes calculating FNs and related time courses for all subjects according to step 4 to step 8.

Furthermore, the pre-processing of fMRI data at step 1 further includes: removing first few time points of fMRI data and performing slice timing correction, head motion correction, spatial normalization, and spatial smoothing.

Furthermore, data representing of each subject's fMRI data at step 1 refers to converting four-dimensional fMRI data into the two-dimensional matrix, which is drawing a three-dimensional image corresponding to each time point extracted from original fMRI data within a brain mask into a row, and then concatenating row vectors along the temporal direction to obtain a matrix X (size: N×S). Here, N represents the number of time points and S represents the number of voxels.

Furthermore, the performing of PCA-based dimension reduction on the two-dimensional matrix data at both the subject level and the group level in sequence along the temporal direction at step 2 further includes: performing PCA-based dimension reduction on the matrix X of each subject to achieve a dimension-reduced matrix (size: n1×S), here n1<N, then concatenating the dimension-reduced matrices of all subjects along the temporal dimension, and performing PCA-based dimension reduction on the concatenated data to further obtain a dimension-reduced matrix (size: n2×S). Here, n2 is the number of components, and n1 is either equal to or greater than n2.

Furthermore, at step 3, the FastICA algorithm or Infomax algorithm is applied for the ICA to obtain group-level components that are used for the initialization of reference components (Rᵢ, i=1, 2, . . . , n2).

Furthermore, 13 voxel-level features calculated based on each reference component Rᵢ at step 4 include four types of features, including:
a first type of voxel-level features includes activation state of each voxel in cerebrospinal fluid, an average activation state of neighbor voxels of each voxel in cerebrospinal fluid, and a mean similarity of activation states between a voxel and neighbor voxels thereof in cerebrospinal fluid; which means, if a cerebrospinal fluid mask has the value of 1 for a specific voxel, then the voxel is activated in the cerebrospinal fluid; otherwise, the voxel is not activated in the cerebrospinal fluid;
a second type of voxel-level features includes activation state of each voxel in white matter, an average activation state of neighbor voxels of each voxel in white matter, and a mean similarity of activation states between a voxel and neighbor voxels thereof in white matter;
a third type of voxel-level features includes activation state of each voxel in brain edge, an average activation state of neighbor voxels of each voxel in brain edge, and a mean similarity of activation states between a voxel and neighbor voxels thereof in brain edge; and
a fourth type of voxel-level features includes a size of connected region of each voxel, a voxel degree of each voxel, an average voxel degree of neighbor voxels of each voxel, and a mean similarity of voxel degrees between a voxel and neighbor voxels thereof; and
calculating the activation state of i-th voxel in cerebrospinal fluid, white matter, or brain edge includes: Active_WMᵢ=WMmask(i), Active_CSFᵢ=CSFmask(i), and Active_BEᵢ=BEmask(i); WMmask(·), CSFmask(·), and BEmask(·) denote that if a voxel is activated in the white matter mask, cerebrospinal fluid mask, or brain edge mask, the feature value is set to 1; otherwise, the feature value is set to 0;
calculating the average activation state of neighbor voxels of i-th voxel in cerebrospinal fluid, white matter, or brain edge includes:

$${ActiveMean\_WM}_{i} = \frac{{\sum }_{j}^{j ϵ {neigh}_{i}} {Active\_WM}_{j}}{{neigh\_len}_{i}} ,$$

$${ActiveMean\_CSF}_{i} = \frac{{\sum }_{j}^{j ϵ {neigh}_{i}} {Active\_CSF}_{j}}{{neigh\_len}_{i}} , and$$

$${ActiveRaito\_BE}_{i} = \frac{{\sum }_{j}^{j ϵ {neigh}_{i}} {Active\_BE}_{j}}{{neigh\_len}_{i}} ;$$

here, the neighᵢ represents the spatially neighbor voxels of the i -th voxel, and the neigh_lenᵢ represents the number of neighbor voxels of the i-th voxel;
calculating the mean similarity of activation states between a voxel and neighbor voxels thereof in cerebrospinal fluid, white matter, or brain edge includes: the similarity between activation states of i-th voxel and j-th voxel in white matter is:

$${Corr\_WM}_{i} J = \{ \begin{matrix}1 & if {Active\_WM}_{i} = {Active\_WM}_{j} \\ 0 & Otherwise\end{matrix}$$

the mean similarity of activation states between the i-th voxel and neighbor voxels thereof in white matter is

$${CorrMean\_WM}_{i} = \frac{{\sum }_{j}^{j ϵ {neigh}_{i}} {Corr\_WM}_{i , j}}{{neigh\_len}_{i}} ;$$

similar to the calculation in white matter, the mean similarity of activation states between the i-th voxel and neighbor voxels thereof in cerebrospinal fluid and brain edge are

$$\\ {CorrMean\_CSF}_{i} = \frac{{\sum }_{j}^{j ϵ {neigh}_{i}} {Corr\_CSF}_{i , j}}{{neigh\_len}_{i}} , and$$

$$\\ {CorrMean\_BE}_{i} = \frac{{\sum }_{j}^{j ϵ {neigh}_{i}} {Corr\_BE}_{i , j}}{{neigh\_len}_{i}} ,$$

respectively;
calculating the voxel degree of i-th voxel includes:

$$\\ {Voxel\_degree}_{i} = {\sum }_{j}^{j ϵ {neigh}_{i}} \frac{1}{\vert {Z}_{i} - {Z}_{j} \vert} ;$$

here, Zᵢ and Zⱼ represent the corresponding z-score of the i-th voxel and the j-th voxel in a component;
calculating the average voxel degree of neighbor voxels of the i-th voxel includes:

$$\\ {Degree\_Mean}_{i} = \frac{{\sum }_{j}^{j ϵ {neigh}_{i}} {Voxel\_degree}_{j}}{{neigh\_len}_{i}} ;$$

calculating the mean similarity of voxel degrees between the i-th voxel and neighbor voxels thereof includes:

$$\\ {CorrMean\_degree}_{i , j} = \frac{{\sum }_{j}^{j ϵ {neigh}_{i}} \frac{1}{{e}^{{}^{} {Voxel \_ degree}_{i} - {Voxel \_ degree}_{j}}}}{{neigh\_len}_{i}} ;$$

and
calculating the size of connected region of each voxel includes: aggregating a voxel into a region by a region growing algorithm, and the region growing is based on Z-scores of voxels in component, finally taking the voxel number of the region as a feature value.

Furthermore, during the construction of the multi-objective function by employing the voxel-level features of each component, each reference component Rᵢ, and the individual subject's data matrix X at step 5, the multi-objective function is as follows:

$$\\ max \{ \begin{matrix}J ( {Y}_{i} ) = {\{ E [ G ( {Y}_{i} ) ] - E [ G ( v ) ] \}}^{2} \\ F ( {Y}_{i} ) = E ( {Y}_{i} \cdot {R}_{i} ) \\ T ( {Y}_{i} ) = - Tr ( {Y}_{i} \cdot L \cdot {Y}_{i}^{{}^{} T} )\end{matrix} ,$$

an optimization target of the multi-objective function includes independence of each component, correspondence between each component and related reference component Rᵢ, and smoothness of each component; here, J(Yᵢ) is a negative entropy of an estimated independent component Yᵢ=wᵢ^{T}·\tilde{X}, which is used to reflect the independence of the component; wᵢ (size: N×1) represents associated unmixing vector; \tilde{X} represents a whitened X; v represents a Gaussian variable with zero mean and unit variance; G(·) represents any non-quadratic function, and E(·) represents the mathematical expectation; F(Yᵢ) is used to represent the correspondence between Yᵢ and Rᵢto ensure comparability of components across subjects; T(Yᵢ) refers to a graph regularization term computed by using 13 voxel-level features, which ensures that voxels with similar features have a higher probability of being grouped into the same independent component, leading to improve smoothness and functional coherence in the estimated independent component; Tr(·) represents a trace of the matrix; L=D−Q represents a Laplace matrix, D represents a degree matrix, and Q computed based on voxel-level features represents similarity between voxels in the component;
regarding Q, an adjacency matrix is calculated to reflect the between-voxel similarity based on each type of voxel-level features, yielding Q₁, Q₂, Q₃, and Q₄, and then each Qᵢ (i=1, 2, 3, 4) is taken independently as Q for removing specific noises or jointly to generate Q (Q=Q₁+Q₂+Q₃+Q₄) for removing all types of noises; to compute each Qᵢ (i=1, 2, 3, 4), first the voxel-level features within the same type are multiplied together to obtain VoxF_i (size: S×1); then a sparse distance matrix WF is calculated based on space information of voxels and finally Qᵢ=WF·VoxF_i·VoxF_i^{T} is calculated; and
regarding the degree matrix D, values of diagonal elements of D are column sums of corresponding adjacency matrix Q.

Furthermore, the normalizing of the multi-objective function at step 5 further includes: normalizing the multi-objective function by an inverse tangent function and an exponential function with base e. The multi-objective function is normalized to avoid an optimization process being dominated by objective functions with large value. The normalized multi-objective function is denoted as:

$$\\ max \{ \begin{matrix}K ( {Y}_{i} ) = \frac{2}{π} \cdot arc tan ( z \cdot {\{ E [ G ( {Y}_{i} ) ] - E [ G ( v ) ] \}}^{2} ) \\ F ( {Y}_{i} ) = E ( {Y}_{i} \cdot {R}_{i} ) \\ U ( {Y}_{i} ) = {e}^{{}^{} \frac{- Tr ( {Y}_{i} \cdot L \cdot {Y}_{{i}_{}}^{{}^{} T} )}{t}}\end{matrix} ,$$

$$\\ z = tan ( F ( {Y}_{i}^{{}^{} 0} ) \cdot \frac{π}{2} ) / {\{ E [ G ( {Y}_{i}^{{}^{} 0} ) ] - E [ G ( v ) ] \}}^{2} ,$$

$$\\ t = - Tr ( {Y}_{i}^{{}^{} 0} \cdot L \cdot {Y}_{i}^{{}^{} {0}^{{}^{} T}} ) / ln ( F ( {Y}_{i}^{{}^{} 0} ) ) ,$$

here, Yᵢ⁰ denotes initial Yᵢ and is i-th group-level IC.

Furthermore, iteratively optimizing the multi-objective function includes based on a linear weighted sum method, changing the multi-objective function to a unified objective function:

P(Yᵢ)=a·K(Yᵢ)+b·F(Yᵢ)+c·U(Yᵢ),
a, b, and c are weights,

$$\\ b = \frac{1}{3 + 3 \cdot {e}^{{}^{} - \frac{1}{3} \cdot ( q - 10 )}} , a = c = \frac{1 - b}{2} ,$$

and q represents the current iteration time;
a method for iteratively optimizing the multi-objective function is a gradient descent method, including:

∇J(Yᵢ)=2·{E[G(Yᵢ)]−E[G(v)]}·E[tanh (Yᵢ)·\tilde{X}],
here E[G(v)]=E[log (cosh (v))] is a constant 0.375, so,

$$\\ K ( {Y}_{i} ) = \frac{2}{π} \cdot z \cdot \frac{1}{1 + {[ z \cdot J ( {Y}_{i} ) ]}^{2}} \cdot ∇ J ( {Y}_{i} ) ;$$

since

$$\\ F ( {Y}_{i} ) = E ( {Y}_{i} \cdot {R}_{i} ) = E [ ( {w}_{i}^{{}^{} T} \cdot \tilde{X} ) \cdot {R}_{i} ] = {w}_{i}^{{}^{} T} \cdot E ( \tilde{X} \cdot {R}_{i} ) ,$$

$$\\ ∇ F ( {Y}_{i} ) = E ( \tilde{X} \cdot {R}_{i} ) ; because U ( {Y}_{i} ) = {e}^{{}^{} \frac{- Tr ( {Y}_{i} \cdot L \cdot {Y}_{{i}_{}}^{{}^{} T} )}{t}} ,$$

$$\\ ∇ U ( {Y}_{i} ) = U ( {Y}_{i} ) \cdot ( - \frac{2}{t} \cdot \tilde{X} \cdot L \cdot {Y}_{i}^{{}^{} T} ) ;$$

as such, the iteration is formulated as follows:

∇P(Yᵢ)=a·∇K(Yᵢ)+b·∇F(Yᵢ)+c·∇U(Yᵢ),
for the iteration, wᵢ is initialized with wᵢ⁰=(Yᵢ⁰·\tilde{X}⁻¹)^{T}, and \tilde{X}⁻¹ represents an inverse of \tilde{X}; the value of wᵢ after q iteration is: wᵢ^{q}=wᵢ^{q-1}+μ·dᵢ^{q-1}; here,

$$\\ {d}_{i} = \frac{∇ P ( {Y}_{i} )}{‖ ∇ P ( {Y}_{i} ) ‖}$$

is the iteration direction; the iteration step μ is determined by backtracing line search; the iteration step μ is initially set to 1, and if a total objective function value increases after each iteration, μ remains value, otherwise, the iteration step μ is halved until objective function value increases;
if ∥wᵢ^{q}−wᵢ^{q-1}∥<10⁻⁵ or q reaches the maximum iteration time, wᵢ^{*}=wᵢ^{q}, go to perform step 7; otherwise, the reference component Rᵢ is updated by using (wᵢ^{q})^{T}·\tilde{X} and then go to perform step 4 to step 5.

The estimating independent component at step 7 uses formula: Yᵢ=(wᵢ^{*})^{T}·\tilde{X}.

The calculating time course of the FN for the individual subject at step 8 further includes: calculating the time course (TC) corresponding to each component in the individual subject based on an estimated component Y and individual subject's data matrix X by formula: TC=E(X·Y⁻¹), here Y⁻¹ represents an inverse of Y and E(·) represents a mathematical expectation.

The calculating FNs and related time courses for all subjects at step 9 further includes calculating each FN and related time courses for each individual subject according to step 4 to step 8.

A computer device is provided. The computer device includes a processor and a memory, the memory stores a computer program, the computer program is executable by the processor to implement the following steps:
step 1 includes preprocessing functional magnetic resonance imaging (NMI) data of each subject and representing four-dimensional data as a two-dimensional matrix;
step 2 includes performing dimension reduction on data of two-dimensional matrices of all subjects at both a subject level and a group level in sequence along a temporal direction by using principal component analysis (PCA);
step 3 includes performing independent component analysis (ICA) on dimension-reduced data to obtain group-level independent components (ICs) and identify FN-related group-level ICs;
step 4 includes calculating 13 voxel-level features for each voxel based on each reference component that is initialized by using each FN-related group-level IC;
step 5 includes constructing a multi-objective function by employing the voxel-level features of each component, each reference component, and an individual subject's data matrix, and then normalizing the multi-objective function;
step 6 includes iteratively optimizing the multi-objective function, if termination condition is not met, updating the reference component and then performing step 4 to step 5 again;
step 7 includes outputting an IC that represents a FN for the individual subject;
step 8 includes calculating time course of the FN for the individual subject;
step 9 includes calculating FNs and related time courses for all subjects according to step 4 to step 8.

A computer-readable storage medium having stored a computer program is provided. The computer program is executable by a processor to implement the following steps:
step 1 includes preprocessing functional magnetic resonance imaging (fMRI) data of each subject and representing four-dimensional data as a two-dimensional matrix;
step 2 includes performing dimension reduction on data of two-dimensional matrices of all subjects at both a subject level and a group level in sequence along a temporal direction by using principal component analysis (PCA);
step 3 includes performing independent component analysis (ICA) on dimension-reduced data to obtain group-level independent components (ICs) and identify FN-related group-level ICs;
step 4 includes calculating 13 voxel-level features for each voxel based on each reference component that is initialized by using each FN-related group-level IC;
step 5 includes constructing a multi-objective function by employing the voxel-level features of each component, each reference component, and an individual subject's data matrix, and then normalizing the multi-objective function;
step 6 includes iteratively optimizing the multi-objective function, if termination condition is not met, updating the reference component and then performing step 4 to step 5 again;
step 7 includes outputting an IC that represents a FN for the individual subject;
step 8 includes calculating time course of the FN for the individual subject;
step 9 includes calculating FNs and related time courses for all subjects according to step 4 to step 8.

### BRIEF DESCRIPTION OF THE DRAWINGS

FIG. 1 is a flowchart diagram of a group information guided smooth independent component analysis method for brain functional network analysis in an embodiment of the present disclosure.

FIG. 2 is a schematic diagram of results obtained by a group information guided smooth independent component analysis (GIG-sICA) method, a dual regression (DR) method and a group information guided ICA (GIG-ICA) method on five groups of simulated data with noise added to cerebrospinal fluid, white matter, brain edge, gray matter, and whole brain, respectively, in an embodiment of the present disclosure.

FIG. 3 shows important regions in four common brain functional networks (including default mode network, sensorimotor network, visual network, and salience network) obtained by performing voxel-level one-sample t-test on all subjects' brain functional networks for GIG-sICA method, DR method, and GIG-ICA method, respectively, in an embodiment of the present disclosure.

FIG. 4 shows group difference between healthy subjects and schizophrenia patients in four common brain functional networks (including default mode network, sensorimotor network, visual network, and salience network) obtained by performing voxel-level two-sample t-test on healthy subjects' and schizophrenia patients' brain functional networks for GIG-sICA method, DR method, and GIG-ICA method, respectively, in an embodiment of the present disclosure.

FIG. 5 is an internal structure diagram of a terminal in an embodiment of the present disclosure.

### DETAILED DESCRIPTION OF THE EMBODIMENT

In order to make purposes, technical solutions and advantages of the present disclosure more clearly understood, the present disclosure is described in further detail below in conjunction with the accompanying drawings and embodiments. It should be understood that the specific embodiments described herein are for the sole purpose of explaining the present disclosure and are not intended to limit the present disclosure.

### A First Embodiment

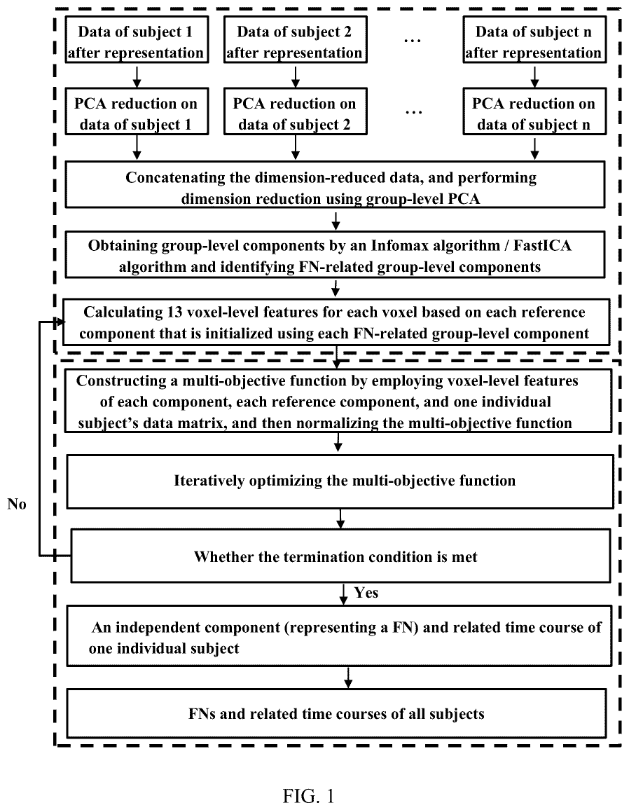

Referring to FIG. 1, the present disclosure provides a group information guided smooth independent component analysis method for brain functional network analysis, including:
step 1 includes preprocessing functional magnetic resonance imaging (fMRI) data of each subject and representing four-dimensional data as a two-dimensional matrix;
step 2 includes performing dimension reduction on data of two-dimensional matrices of all subjects at both a subject level and a group level in sequence along a temporal direction by using principal component analysis (PCA);
step 3 includes performing independent component analysis (ICA) on dimension-reduced data to obtain group-level independent components (ICs) and identify FN-related group-level ICs;
step 4 includes calculating 13 voxel-level features for each voxel based on each reference component that is initialized by using each FN-related group-level IC;
step 5 includes constructing a multi-objective function by employing the voxel-level features of each component, each reference component, and an individual subject's data matrix, and then normalizing the multi-objective function;
step 6 includes iteratively optimizing the multi-objective function, if termination condition is not met, updating the reference component and then performing step 4 to step 5 again;
step 7 includes outputting an IC that represents a FN for the individual subject;
step 8 includes calculating time course of the FN for the individual subject;
step 9 includes calculating FNs and related time courses for all subjects according to step 4 to step 8.

Compared with the related art, the present disclosure has following advantages: the present disclosure directly enhances the smoothness, independence, and correspondence of the FNs through a multi-objective function that includes a graph regularization function, negentropy function, and similarity function. Firstly, the graph regularization function is added for improving network spatial smoothness, which overcomes a limitation of the GIG-ICA method that does not optimize smoothness of extracted components; and secondly, voxel-level features are introduced as a guideline in the process of constructing the multi-objective function, so that spatially adjacent voxels or voxels with similar functions and features are more likely located in the same brain functional network, enhancing spatial smoothness and coherence. A notable characteristic of this method is its flexibility, allowing users to selectively weaken the influence raised by various noises by utilizing voxel-level features either independently or in combination.

In an embodiment, the pre-processing of fMRI data at step 1 may further include: removing first few time points of fMRI data and performing slice timing correction, head motion correction, spatial normalization, and spatial smoothing.

In an embodiment, data representing of each subject's fMRI data at step 1 may refer to converting four-dimensional fMRI data into the two-dimensional matrix, which is drawing a three-dimensional image corresponding to each time point extracted from original fMRI data within a brain mask into a row, and then concatenating row vectors along the temporal direction to obtain a matrix X (size: N×S). Here, N represents the number of time points and S represents the number of voxels.

In an embodiment, the performing of PCA-based dimension reduction on the two-dimensional matrix data at both the subject level and the group level in sequence along the temporal direction at step 2 further includes: performing PCA-based dimension reduction on the matrix X of each subject to achieve a dimension-reduced matrix (size: n1×S), here n1<N, then concatenating the dimension-reduced matrices of all subjects along the temporal dimension, and performing PCA-based dimension reduction on the concatenated data to further obtain a dimension-reduced matrix (size: n2×S). Here, n2 is the number of components, and n1 is either equal to or greater than n2.

In an embodiment, at step 3, the FastICA algorithm or Infomax algorithm is applied for the ICA to obtain group-level components that are used for the initialization of reference components (Rᵢ, i=1, 2, . . . , n2).

In an embodiment, 13 voxel-level features calculated based on each reference component Rᵢ at step 4 may include four types of features, including:
a first type of voxel-level features includes activation state of each voxel in cerebrospinal fluid, an average activation state of neighbor voxels of each voxel in cerebrospinal fluid, and a mean similarity of activation states between a voxel and neighbor voxels thereof in cerebrospinal fluid; which means, if a cerebrospinal fluid mask has the value of 1 for a specific voxel, then the voxel is activated in the cerebrospinal fluid; otherwise, the voxel is not activated in the cerebrospinal fluid;
a second type of voxel-level features includes activation state of each voxel in white matter, an average activation state of neighbor voxels of each voxel in white matter, and a mean similarity of activation states between a voxel and neighbor voxels thereof in white matter;
a third type of voxel-level features includes activation state of each voxel in brain edge, an average activation state of neighbor voxels of each voxel in brain edge, and a mean similarity of activation states between a voxel and neighbor voxels thereof in brain edge; and
a fourth type of voxel-level features includes a size of connected region of each voxel, a voxel degree of each voxel, an average voxel degree of neighbor voxels of each voxel, and a mean similarity of voxel degrees between a voxel and neighbor voxels thereof; and
calculating the activation state of i-th voxel in cerebrospinal fluid, white matter, or brain edge includes: Active_WMᵢ=WMmask(i), Active_CSFᵢ=CSFmask(i), and Active_BEᵢ=BEmask(i); WMmask(·), CSFmask(·), and BEmask(·) denote that if a voxel is activated in the white matter mask, cerebrospinal fluid mask, or brain edge mask, the feature value is set to 1; otherwise, the feature value is set to 0;
calculating the average activation state of neighbor voxels of i-th voxel in cerebrospinal fluid, white matter, or brain edge includes:

$$\\ {ActiveMean\_WM}_{i} = \frac{{\sum }_{j}^{j ϵ {neigh}_{i}} {Active\_WM}_{j}}{{neigh\_len}_{i}} ,$$

$$\\ {ActiveMean\_CSF}_{i} = \frac{{\sum }_{j}^{j ϵ {neigh}_{i}} {Active\_CSF}_{j}}{{neigh\_len}_{i}} , and$$

$$\\ {ActiveRaito\_BE}_{i} = \frac{{\sum }_{j}^{j ϵ {neigh}_{i}} {Active\_BE}_{j}}{{neigh\_len}_{i}} ;$$

here, the neighᵢ represents the spatially neighbor voxels of the i-th voxel, and the neigh_lenᵢ represents the number of neighbor voxels of the i-th voxel;
calculating the mean similarity of activation states between a voxel and neighbor voxels thereof in cerebrospinal fluid, white matter, or brain edge includes: the similarity between activation states of i-th voxel and j-th voxel in white matter is:

$$\\ {Corr\_WM}_{i , j} = \{ \begin{matrix}1 & if {Active\_WM}_{i} = {Active\_WM}_{j} \\ 0 & Otherwise\end{matrix}$$

the mean similarity of activation states between the i-th voxel and neighbor voxels thereof in white matter is

$$\\ {CorrMean\_WM}_{i} = \frac{{\sum }_{j}^{j ϵ {neigh}_{i}} {Corr\_WM}_{i , j}}{{neigh\_len}_{i}} ;$$

similar to the calculation in white matter, the mean similarity of activation states between the i-th voxel and neighbor voxels thereof in cerebrospinal fluid and brain edge are

$$\\ {CorrMean\_CSF}_{i} = \frac{{\sum }_{j}^{j ϵ {neigh}_{i}} {Corr\_CSF}_{i , j}}{{neigh\_len}_{i}} , and$$

$$\\ {CorrMean\_BE}_{i} = \frac{{\sum }_{j}^{j ϵ {neigh}_{i}} {Corr\_BE}_{i , j}}{{neigh\_len}_{i}} ,$$

respectively;
calculating the voxel degree of i-th voxel includes:

$$\\ {Voxel\_degree}_{i} = {\sum }_{j}^{j ϵ {neigh}_{i}} \frac{1}{\vert {Z}_{i} - {Z}_{j} \vert} ;$$

here, Zᵢ and Zⱼ represent the corresponding z-score of the i-th voxel and the j-th voxel in a component;
calculating the average voxel degree of neighbor voxels of the i-th voxel includes:

$${Degree\_Mean}_{i} = \frac{{\sum }_{j}^{{jϵneigh}_{i}} {Voxel\_degree}_{j}}{{neigh\_len}_{i}} ;$$

calculating the mean similarity of voxel degrees between the i-th voxel and neighbor voxels thereof includes:

$${CorrMean\_degree}_{i , j} = \frac{{\sum }_{j}^{j ϵ {neigh}_{i} \frac{1}{{e}^{{Voxel\_degree}_{i} - {Voxel\_degree}_{j}}}}}{{neigh\_len}_{i}} ;$$

and
calculating the size of connected region of each voxel includes: aggregating a voxel into a region by a region growing algorithm, and the region growing is based on Z-scores of voxels in component, finally taking the voxel number of the region as a feature value.

In an embodiment, during the construction of the multi-objective function by employing the voxel-level features of each component, each reference component Rᵢ, and the individual subject's data matrix X at step 5, the multi-objective function is as follows:

$$max \{ \begin{matrix}J ( {Y}_{i} ) = {\{ E [ G ( {Y}_{i} ) ] - E [ G ( v ) ] \}}^{2} \\ F ( {Y}_{i} ) = E ( {Y}_{i} \cdot {R}_{i} ) \\ T ( {Y}_{i} ) = - Tr ( {Y}_{i} \cdot L \cdot {Y}_{i}^{T} )\end{matrix} ,$$

an optimization target of the multi-objective function includes independence of each component, correspondence between each component and related reference component Rᵢ, and smoothness of each component; here, J(Yᵢ) is a negative entropy of an estimated independent component Yᵢ=wᵢ^{T}·\tilde{X}, which is used to reflect the independence of the component; wᵢ (size: N×1) represents associated unmixing vector; \tilde{X} represents a whitened X; v represents a Gaussian variable with zero mean and unit variance; G(·) represents any non-quadratic function, and E(·) represents the mathematical expectation; F(Yᵢ) is used to represent the correspondence between Yᵢ and Rᵢ to ensure comparability of components across subjects; T(Yᵢ) refers to a graph regularization term computed by using 13 voxel-level features, which ensures that voxels with similar features have a higher probability of being grouped into the same independent component, leading to improve smoothness and functional coherence in the estimated independent component; Tr(·) represents a trace of the matrix; L=D−Q represents a Laplace matrix, D represents a degree matrix, and Q computed based on voxel-level features represents similarity between voxels in the component;
regarding Q, an adjacency matrix is calculated to reflect the between-voxel similarity based on each type of voxel-level features, yielding Q₁, Q₂, Q₃, and Q₄, and then each Qᵢ (i=1, 2, 3, 4) is taken independently as Q for removing specific noises or jointly to generate Q (Q=Q₁+Q₂+Q₃+Q₄) for removing all types of noises; to compute each Qᵢ (i=1, 2, 3, 4), first the voxel-level features within the same type are multiplied together to obtain VoxF_i (size: S×1); then a sparse distance matrix WF is calculated based on space information of voxels and finally Qᵢ=WF·VoxF_i·VoxF_i^{T} is calculated; and
regarding the degree matrix D, values of diagonal elements of D are column sums of corresponding adjacency matrix Q.

In an embodiment, the normalizing of the multi-objective function at step 5 may further include: normalizing the multi-objective function by an inverse tangent function and an exponential function with base e. The multi-objective function is normalized to avoid an optimization process being dominated by objective functions with large value. The normalized multi-objective function is denoted as:

$$max \{ \begin{matrix}K ( {Y}_{i} ) = \frac{2}{π} \cdot arctan ( z \cdot {\{ E [ G ( {Y}_{i} ) ] - E [ G ( v ) ] \}}^{2} ) \\ F ( {Y}_{i} ) = E ( {Y}_{i} \cdot {R}_{i} ) \\ U ( {Y}_{i} ) = {e}^{\frac{- T r ( {Y}_{i} \cdot L \cdot {Y}_{i}^{T} )}{t}}\end{matrix} ,$$

$$z = tan ( F ( {Y}_{i}^{0} ) \cdot \frac{π}{2} ) / {\{ E [ G ( {Y}_{i}^{0} ) ] - E [ G ( v ) ] \}}^{2} , t = - Tr ( {Y}_{i}^{0} \cdot L \cdot {Y}_{i}^{{0}^{T}} ) / ln ( F ( {Y}_{i}^{0} ) ) ,$$

here, Yᵢ0 denotes initial Yᵢ and is i-th group-level IC.

In an embodiment, iteratively optimizing the multi-objective function may include based on a linear weighted sum method, changing the multi-objective function to a unified objective function:

P(Yᵢ)=a·K(Yᵢ)+b·F(Yᵢ)+c·U(Yᵢ),
a, b, and c are weights,

$$b = \frac{1}{3 + 3 \cdot {e}^{- \frac{1}{3} ( q - 10 )}} ,$$

$$a = c = \frac{1 - b}{2} ,$$

and q represents the current iteration time;
a method for iteratively optimizing the multi-objective function is a gradient descent method, including:

∇J(Yᵢ)=2·{E[G(Yᵢ)]−E[G(v)]}·E[tanh (Yᵢ)·\tilde{X}],
here E[G(v)]=E[log (cosh (v))] is a constant 0.375 , so,

$$K ( {Y}_{i} ) = \frac{2}{π} \cdot z \cdot \frac{1}{1 + {[ z \cdot J ( {Y}_{i} ) ]}^{2}} \cdot ∇ J ( {Y}_{i} ) ;$$

since F(Yᵢ)=E(Yᵢ·Rᵢ)=E[(wᵢ^{T}·\tilde{X})·Rᵢ]=wᵢ^{T}·E(\tilde{X}·Rᵢ), ∇F(Yᵢ)=E(\tilde{X}·Rᵢ);
because

$$U ( {Y}_{i} ) = e \frac{- T r ( {Y}_{i} \cdot L \cdot {Y}_{i}^{T} )}{t} , ∇ U ( {Y}_{i} ) = U ( {Y}_{i} ) \cdot ( - \frac{2}{t} \cdot \tilde{X} \cdot L \cdot {Y}_{i}^{T} ) ;$$

as such, the iteration is formulated as follows:

∇P(Yᵢ)=a·∇K(Yᵢ)+b·∇F(Yᵢ)+c·∇U(Yᵢ),
for the iteration, wᵢ is initialized with wᵢ⁰=(Yᵢ⁰−\tilde{X}⁻¹)^{T}, and \tilde{X}⁻¹ represents an inverse of \tilde{X}; the value of wᵢ after q iteration is: wᵢ^{q}=wᵢ^{q-1}+μ·dᵢ^{q-1}; here,

$${d}_{i} = \frac{∇ P ( {Y}_{i} )}{‖ ∇ P ( {Y}_{i} ) ‖}$$

is the iteration direction; the iteration step μ is determined by backtracing line search; the iteration step μ is initially set to 1, and if a total objective function value increases after each iteration, μ remains value, otherwise, the iteration step μ is halved until objective function value increases; and
if ∥wᵢ^{q}−wᵢ^{q-1}∥<10⁻⁵ or q reaches the maximum iteration time, wᵢ^{*}=wᵢ^{q}, go to perform step 7; otherwise, the reference component Rᵢ is updated by using (wᵢ^{q})^{T}·\tilde{X} and then go to perform step 4 to step 5.

In an embodiment, the estimating independent component at step 7 may use formula:

Yᵢ=(wᵢ^{*})^{T}·\tilde{X}.

In an embodiment, the calculating time course of the FN for the individual subject at step 8 may further include: calculating the time course (TC) corresponding to each component in the individual subject based on an estimated component Y and individual subject's data matrix X by formula: TC=E(X·Y⁻¹), here Y⁻¹ represents an inverse of Y and E(·) represents a mathematical expectation.

In an embodiment, the calculating FNs and related time courses for all subjects at step 9 may further include calculating each FN and related time courses for each individual subject according to step 4 to step 8.

In the present embodiment, initial simulated data may be generated by a SimTB toolbox, including 200 subjects and corresponding ground truth. In the initial simulated data, every subject includes 150 time points, 148×148 voxels, and 8 ICs. Noise is added separately to the cerebrospinal fluid, white matter, brain edge, gray matter, and whole brain of the initial simulated data to generate five groups of simulated data with different noises. Real fMRI data in the present embodiment are from 144 healthy subjects and 137 schizophrenia patients.

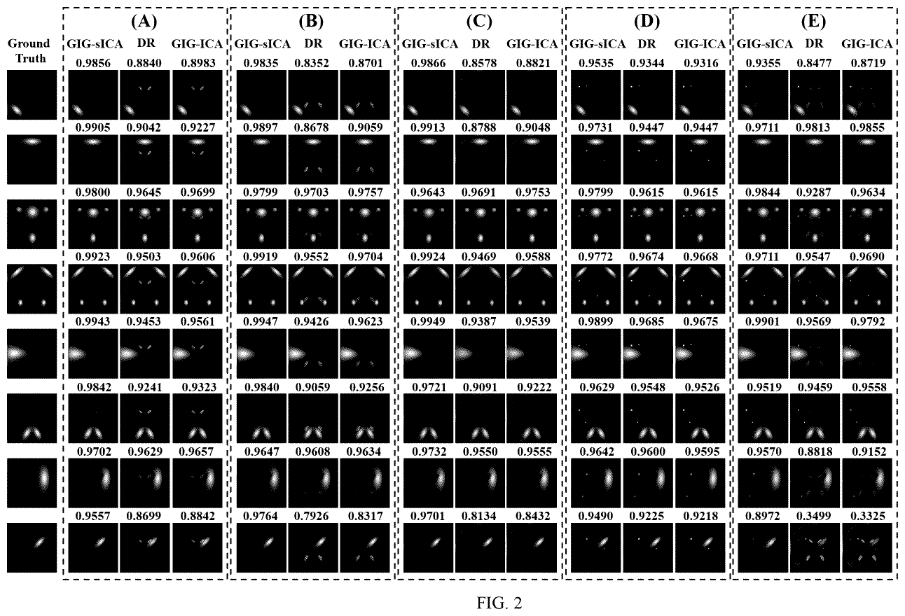

FIG. 2 is a schematic diagram of results obtained by a group information guided smooth independent component analysis (GIG-sICA) method, a dual regression (DR) method and a group information guided ICA (GIG-ICA) method on five groups of simulated data with noise added to cerebrospinal fluid, white matter, brain edge, gray matter, and whole brain, respectively, in an embodiment of the present disclosure. Referring to FIG. 2, (A)-(E) represents the results on the data that are added noise in cerebrospinal fluid, white matter, brain edge, gray matter, and whole brain, respectively. Results show that the GIG-sICA method yields smoother and more accuracy functional networks than the other two methods regardless of data with any kind of noise.

FIG. 3 shows important regions in four common brain functional networks (including default mode network, sensorimotor network, visual network, and salience network) obtained by performing voxel-level one-sample t-test on all subjects' brain functional networks for GIG-sICA method, DR method, and GIG-ICA method, respectively, in an embodiment of the present disclosure. Referring to FIG. 3, (A)-(D) represents the default mode network, sensorimotor network, visual network, and salience network, respectively. Compared with the FNs estimated by the DR method and GIG-ICA method, the GIG-sICA method successfully removes most of the noises in cerebrospinal fluid, white matter, brain edge and gray matter, and extracts smooth and realistic FNs.

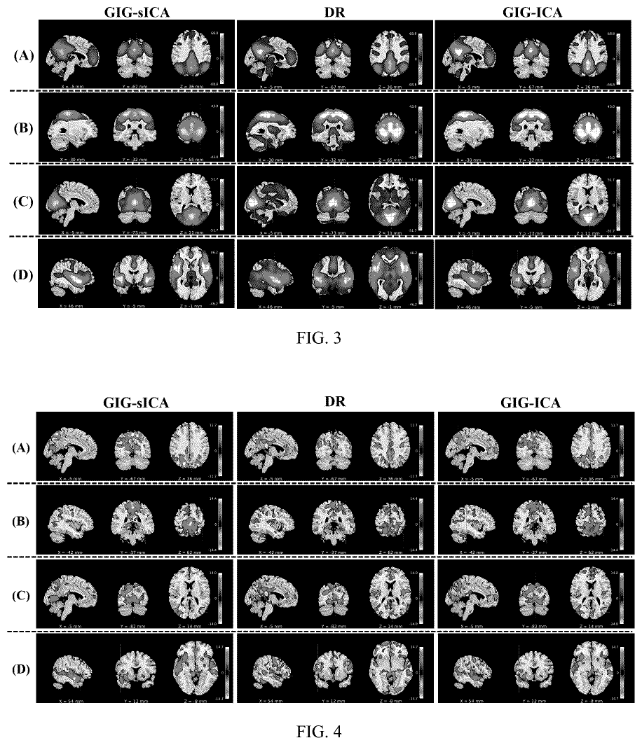

FIG. 4 shows group difference between healthy subjects and schizophrenia patients in four common brain functional networks (including default mode network, sensorimotor network, visual network, and salience network) obtained by performing voxel-level two-sample t-test on healthy subjects' and schizophrenia patients' brain functional networks for GIG-sICA method, DR method, and GIG-ICA method, respectively, in an embodiment of the present disclosure. The dark area represents the voxel positions where the network activation of healthy subjects is greater than schizophrenia patients. The difference obtained by GIG-sICA is larger and smoother than the DR and GIG-ICA methods.

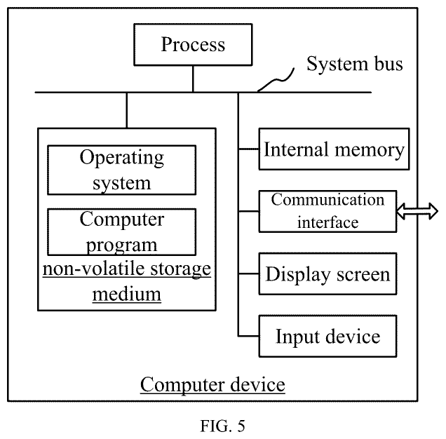

In an embodiment, a computer device is provided, which may be a terminal or a server. Taking a terminal as an example, an internal structure diagram of the terminal may be shown in FIG. 5. The computer device may include a processor, a memory, a communication interface, a display screen and an input device connected via a system bus. The processor of the computer device is configured to provide computing and control capabilities. The memory of the computer device may include a non-volatile storage medium and an internal memory. The non-volatile storage medium may store an operating system and a computer program. The internal memory may provide an environment for operation of the operating system and the computer program in the non-volatile storage media. The communication interface of the computer device is configured for wired or wireless communication with external terminals, and the wireless manner may be implemented via WIFI, carrier networks, NFC (Near Field communication), or other technologies. The computer program may implement the GIG-sICA method when the computer program is executed by the processor. The display screen of the computer device may be a liquid crystal display screen or an electronic ink display screen, and the input device of the computer device may be a touch layer covered on the display screen, or a key, trackball or trackpad set on a shell of the computer device, or an external keyboard, trackpad, or mouse.

One skilled in the art may understand that the structure shown in FIG. 5 is only a block diagram of a part of the structure related to the present disclosure and does not constitute a limitation of the computer device to which the present disclosure is applied. A specific computer device may include more or less components than that shown in the figure, a combination of some components, or a different component arrangement.

In an embodiment, a computer device is provided. The computer device includes a processor and a memory, the memory stores a computer program, the computer program is executable by the processor to implement the following steps:
step 1 includes preprocessing functional magnetic resonance imaging (fMRI) data of each subject and representing four-dimensional data as a two-dimensional matrix;
step 2 includes performing dimension reduction on data of two-dimensional matrices of all subjects at both a subject level and a group level in sequence along a temporal direction by using principal component analysis (PCA);
step 3 includes performing independent component analysis (ICA) on dimension-reduced data to obtain group-level independent components (ICs) and identify FN-related group-level ICs;
step 4 includes calculating 13 voxel-level features for each voxel based on each reference component that is initialized by using each FN-related group-level IC;
step 5 includes constructing a multi-objective function by employing the voxel-level features of each component, each reference component, and an individual subject's data matrix, and then normalizing the multi-objective function;
step 6 includes iteratively optimizing the multi-objective function, if termination condition is not met, updating the reference component and then performing step 4 to step 5 again;
step 7 includes outputting an IC that represents a FN for the individual subject;
step 8 includes calculating time course of the FN for the individual subject;
step 9 includes calculating FNs and related time courses for all subjects according to step 4 to step 8.

In an embodiment, a computer-readable storage medium having stored a computer program is provided. The computer program is executable by a processor to implement the following steps:
step 1 includes preprocessing functional magnetic resonance imaging (fMRI) data of each subject and representing four-dimensional data as a two-dimensional matrix;
step 2 includes performing dimension reduction on data of two-dimensional matrices of all subjects at both a subject level and a group level in sequence along a temporal direction by using principal component analysis (PCA);
step 3 includes performing independent component analysis (ICA) on dimension-reduced data to obtain group-level independent components (ICs) and identify FN-related group-level ICs;
step 4 includes calculating 13 voxel-level features for each voxel based on each reference component that is initialized by using each FN-related group-level IC;
step 5 includes constructing a multi-objective function by employing the voxel-level features of each component, each reference component, and an individual subject's data matrix, and then normalizing the multi-objective function;
step 6 includes iteratively optimizing the multi-objective function, if termination condition is not met, updating the reference component and then performing step 4 to step 5 again;
step 7 includes outputting an IC that represents a FN for the individual subject;
step 8 includes calculating time course of the FN for the individual subject;
step 9 includes calculating FNs and related time courses for all subjects according to step 4 to step 8.

One skilled in the art may understand that all or part of the process of implementing the method in the above embodiments may be accomplished by instructing the relevant hardware by a computer program, the computer program may be stored in a non-volatile computer readable storage medium, and the computer program may include a process such as that of the method in the above embodiments when executed. Any reference to a memory, a storage, a database or other medium used in the embodiments provided in the present disclosure may include at least one of a non-volatile memory and a volatile memory. The non-volatile memory may include a Read-Only memory (ROM), a magnetic tape, a floppy disk, a flash memory, or an optical memory. The volatile memory may include a Random Access Memory (RAM) or an external cache memory. As an illustration rather than a limitation, the RAM may come in many forms, such as a Static Random Access Memory (SRAM), a Dynamic Random Access Memory (DRAM), and the like. The technical features of the above-described embodiments may be combined in any combination. For the sake of brevity of description, all possible combinations of the technical features in the above embodiments are not described. However, as long as there is no contradiction between the combinations of these technical features, all should be considered as within the scope of this disclosure.

The technical features of the above-mentioned embodiments can be combined arbitrarily. In order to make the description concise, not all possible combinations of the technical features are described in the embodiments. However, as long as there is no contradiction in the combination of these technical features, the combinations should be considered as in the scope of the present disclosure.

The above-described embodiments are only several implementations of the present disclosure, and the descriptions are relatively specific and detailed, but they should not be construed as limiting the scope of the present disclosure. It should be understood by those of ordinary skill in the art that various modifications and improvements can be made without departing from the concept of the present disclosure, and all fall within the protection scope of the present disclosure. Therefore, the patent protection of the present disclosure shall be defined by the appended claims.

What is claimed is:

1. A group information guided smooth independent component analysis method for brain functional network analysis, comprising following steps:
step 1 comprises preprocessing functional magnetic resonance imaging (fMRI) data of each subject and representing four-dimensional data as a two-dimensional matrix;
step 2 comprises performing dimension reduction on data of two-dimensional matrices of all subjects at both a subject level and a group level in sequence along a temporal direction by using principal component analysis (PCA);
step 3 comprises performing independent component analysis (ICA) on dimension-reduced data to obtain group-level independent components (ICs) and identify FN-related group-level ICs;
step 4 comprises calculating 13 voxel-level features for each voxel based on each reference component that is initialized by using each FN-related group-level IC;
step 5 comprises constructing a multi-objective function by employing the voxel-level features of each component, each reference component, and an individual subject's data matrix, and then normalizing the multi-objective function;
step 6 comprises iteratively optimizing the multi-objective function, if termination condition is not met, updating the reference component and then performing step 4 to step 5 again;
step 7 comprises outputting an IC that represents a functional network (FN) for the individual subject;
step 8 comprises calculating time course of the FN for the individual subject;
step 9 comprises calculating FNs and related time courses for all subjects according to step 4 to step 8.

2. The group information guided smooth independent component analysis method for brain functional network analysis of claim 1, wherein the pre-processing of fMRI data at step 1 further comprises: removing first few time points of fMRI data and performing slice timing correction, head motion correction, spatial normalization, and spatial smoothing.

3. The group information guided smooth independent component analysis method for brain functional network analysis of claim 1, wherein data representing of each subject's fMRI data at step 1 refers to converting four-dimensional fMRI data into the two-dimensional matrix, which is drawing a three-dimensional image corresponding to each time point extracted from original fMRT data within a brain mask into a row, and then concatenating row vectors along the temporal direction to obtain a matrix X (size: N×S), wherein N represents the number of time points and S represents the number of voxels.

4. The group information guided smooth independent component analysis method for brain functional network analysis of claim 1, wherein the performing of PCA-based dimension reduction on the two-dimensional matrix data at both the subject level and the group level in sequence along the temporal direction at step 2 further comprises: performing PCA-based dimension reduction on the matrix X of each subject to achieve a dimension-reduced matrix (size: n1×S), wherein n1<N, then concatenating the dimension-reduced matrices of all subjects along the temporal dimension, and performing PCA-based dimension reduction on the concatenated data to further obtain a dimension-reduced matrix (size: n2×S), wherein, n2 is the number of components, and n1 is either equal to or greater than n2.

5. The group information guided smooth independent component analysis method for brain functional network analysis of claim 1, wherein at step 3, the FastICA algorithm or Infomax algorithm is applied for the ICA to obtain group-level components that are used for the initialization of reference components (Rᵢ, i=1, 2, . . . , n2).

6. The group information guided smooth independent component analysis method for brain functional network analysis of claim 1, wherein 13 voxel-level features calculated based on each reference component at step 4 comprise four types of features, comprising:
a first type of voxel-level features comprises activation state of each voxel in cerebrospinal fluid, an average activation state of neighbor voxels of each voxel in cerebrospinal fluid, and a mean similarity of activation states between a voxel and neighbor voxels thereof in cerebrospinal fluid;
a second type of voxel-level features comprises activation state of each voxel in white matter, an average activation state of neighbor voxels of each voxel in white matter, and a mean similarity of activation states between a voxel and neighbor voxels thereof in white matter;
a third type of voxel-level features comprises activation state of each voxel in brain edge, an average activation state of neighbor voxels of each voxel in brain edge, and a mean similarity of activation states between a voxel and neighbor voxels thereof in brain edge; and
a fourth type of voxel-level features comprises a size of connected region of each voxel, a voxel degree of each voxel, an average voxel degree of neighbor voxels of each voxel, and a mean similarity of voxel degrees between a voxel and neighbor voxels thereof; and
calculating the activation state of i-th voxel in cerebrospinal fluid, white matter, or brain edge comprises: Active_WMᵢ=WMmask(i), Active_CSFᵢ=CSFmask(i), and Active_BEᵢ=BEmask(i); WMmask(·), CSFmask(·), and BEmask(·) denote that if a voxel is activated in the white matter mask, cerebrospinal fluid mask, or brain edge mask, the feature value is set to 1; otherwise, the feature value is set to 0;
calculating the average activation state of neighbor voxels of i-th voxel in cerebrospinal fluid, white matter, or brain edge comprises:
$${ActiveMean\_WM}_{i} = \frac{{\sum }_{j}^{j ϵ {neigh}_{i} {Active\_WM}_{j}}}{{neigh\_len}_{i}} ,$$
$${ActiveMean\_CSF}_{i} = \frac{{\sum }_{j}^{j ϵ {neigh}_{i} {Active\_CSF}_{j}}}{{neigh\_len}_{i}} ,$$
$$and$$
$${ActiveRatio\_BE}_{i} = \frac{{\sum }_{j}^{j ϵ {neigh}_{i} {Active\_BE}_{j}}}{{neigh\_len}_{i}} ;$$
wherein, the neighᵢ represents the spatially neighbor voxels of the i-th voxel, and the neigh_lenᵢ represents the number of neighbor voxels of the i-th voxel;
calculating the mean similarity of activation states between a voxel and neighbor voxels thereof in cerebrospinal fluid, white matter, or brain edge comprises: the similarity between activation states of i-th voxel and j-th voxel in white matter is:
$${Corr\_WM}_{i , j} = \{ \begin{matrix}1 & if {Active\_WM}_{i} = {Active\_WM}_{j} \\ 0 & Otherwise\end{matrix}$$
the mean similarity of activation states between the i-th voxel and neighbor voxels thereof in white matter is
$${C orrMean\_WM}_{i} = \frac{{\sum }_{j}^{j ϵ {neigh}_{i} {Corr\_WM}_{i , j}}}{{neigh\_len}_{i}} ;$$
the mean similarity of activation states between the i-th voxel and neighbor voxels thereof in cerebrospinal fluid and brain edge are
$${C orrMean\_CSF}_{i} = \frac{{\sum }_{j}^{j ϵ {neigh}_{i} {Corr\_CSF}_{i , j}}}{{neigh\_len}_{i}} ,$$
$$and$$
$${C orrMean\_BE}_{i} = \frac{{\sum }_{j}^{j ϵ {neigh}_{i} {Corr\_BE}_{i , j}}}{{neigh\_len}_{i}} ,$$
respectively;
calculating the voxel degree of i-th voxel comprises:
$${Voxel\_degree}_{i} = {\sum }_{j}^{j ϵ {neigh}_{i}} \frac{1}{\vert {Z}_{i} - {Z}_{j} \vert} ;$$
wherein, Zᵢ and Zⱼ represent the corresponding z-score of the i-th voxel and the j-th voxel in a component;
calculating the average voxel degree of neighbor voxels of the i-th voxel comprises:
$${Degree\_Mean}_{i} = \frac{{\sum }_{j}^{j ϵ {neigh}_{i}} {Vo xel\_degree}_{j}}{{neigh\_le n}_{i}} ,$$
calculating the mean similarity of voxel degrees between the i-th voxel and neighbor voxels thereof comprises:
$${C orrMean\_degree}_{i , j} = \frac{{\sum }_{j}^{j ϵ {neigh}_{i} \frac{1}{{e}^{{Voxel\_degree}_{i} - {Voxel\_degree}_{j}}}}}{{neigh\_len}_{i}} ;$$
and
calculating the size of connected region of each voxel comprises: aggregating a voxel into a region by a region growing algorithm, and the region growing is based on Z-scores of voxels in component, finally taking the voxel number of the region as a feature value.

7. The group information guided smooth independent component analysis method for brain functional network analysis of claim 1, wherein during the construction of the multi-objective function by employing the voxel-level features of each component, each reference component, and the individual subject's data matrix at step 5, the multi-objective function is as follows:
$$max \{ \begin{matrix}J ( {Y}_{i} ) = {\{ E [ G ( {Y}_{i} ) ] - E [ G ( v ) ] \}}^{2} \\ F ( {Y}_{i} ) = E ( {Y}_{i} \cdot {R}_{i} ) \\ T ( {Y}_{i} ) = - Tr ( {Y}_{i} \cdot L \cdot {Y}_{i}^{T} )\end{matrix} ,$$
an optimization target of the multi-objective function comprises independence of each component, correspondence between each component and related reference component Rᵢ, and smoothness of each component; wherein, J(Yᵢ) is a negative entropy of an estimated independent component Yᵢ=wᵢ^{T}·\tilde{X}, which is used to reflect the independence of the component; wᵢ (size: N×1) represents associated unmixing vector; \tilde{X} represents a whitened X; v represents a Gaussian variable with zero mean and unit variance; G(·) represents any non-quadratic function, and E(·) represents the mathematical expectation; F(Yᵢ) is used to represent the correspondence between Yᵢ and Rᵢ to ensure comparability of components across subjects; T(Yᵢ) refers to a graph regularization term computed by using 13 voxel-level features; Tr(·) represents a trace of the matrix; L=D−Q represents a Laplace matrix, wherein D represents a degree matrix, and Q computed based on voxel-level features represents similarity between voxels in the component;
regarding Q, an adjacency matrix is calculated to reflect the between-voxel similarity based on each type of voxel-level features, yielding Q₁, Q₂, Q₃, and Q₄, and then each Qᵢ (i=1, 2, 3, 4) is taken independently as Q for removing specific noises or jointly to generate Q (Q=Q₁+Q₂+Q₃+Q₄) for removing all types of noises; to compute each Qᵢ (i=1, 2, 3, 4), first the voxel-level features within the same type are multiplied together to obtain VoxF_i (size: S×1); then a sparse distance matrix WF is calculated based on space information of voxels and finally Qᵢ=WF·VoxF_i·VoxF_i^{T} is calculated; and
regarding the degree matrix D, values of diagonal elements of D are column sums of corresponding adjacency matrix Q.

8. The group information guided smooth independent component analysis method for brain functional network analysis of claim 7, wherein the normalizing of the multi-objective function at step 5 further comprises: normalizing the multi-objective function by an inverse tangent function and an exponential function with base e;
the normalized multi-objective function is denoted as:
$$max \{ \begin{matrix}K ( {Y}_{i} ) = \frac{2}{π} \cdot arc tan ( z \cdot {\{ E [ G ( {Y}_{i} ) ] - E [ G ( v ) ] \}}^{2} ) \\ F ( {Y}_{i} ) = E ( {Y}_{i} \cdot {R}_{i} ) \\ U ( {Y}_{i} ) = {e}^{\frac{- T r ( {Y}_{i} \cdot L \cdot {Y}_{i}^{T} )}{t}}\end{matrix} ,$$
$$z = tan ( F ( {Y}_{i}^{0} ) \cdot \frac{π}{2} ) / {\{ E [ G ( {Y}_{i}^{0} ) ] - E [ G ( v ) ] \}}^{2} , t = - Tr ( {Y}_{i}^{0} \cdot L \cdot {Y}_{i}^{{0}^{T}} ) / ln ( F ( {Y}_{i}^{0} ) ) ,$$
wherein, Yᵢ⁰ denotes initial Yᵢ and is i-th group-level IC.

9. The group information guided smooth independent component analysis method for brain functional network analysis of claim 8, wherein iteratively optimizing the multi-objective function further comprises based on a linear weighted sum method, changing the multi-objective function to a unified objective function:
P(Yᵢ)=a·K(Yᵢ)+b·F(Yᵢ)+c·U(Yᵢ),
a, b, and c are weights, wherein
$$b = \frac{1}{3 + 3 \cdot {e}^{- \frac{1}{3} \cdot ( q - 10 )}} , a = c = \frac{1 - b}{2} ,$$
and q represents the current iteration time;
a method for iteratively optimizing the multi-objective function is a gradient descent method, comprising:
∇J(Yᵢ)=2·{E[G(Yᵢ)]−E[G(v)]}·E[tanh (Yᵢ)·\tilde{X}],
wherein E[G(v)]=E[log (cosh (v))] is a constant 0.375, so,
$$K ( {Y}_{i} ) = \frac{2}{π} \cdot z \cdot \frac{1}{1 + {[ z \cdot J ( {Y}_{i} ) ]}^{2}} \cdot ∇ J ( {Y}_{i} ) ;$$
since F(Yᵢ)=E(Yᵢ·Rᵢ)=E[(wᵢ^{T}·\tilde{X})·Rᵢ]=wᵢ^{T}·E(\tilde{X}·Rᵢ), ∇F(Yᵢ)=E(\tilde{X}·Rᵢ);
because
$$U ( {Y}_{i} ) = {e}^{\frac{- T r ( {Y}_{i} \cdot L \cdot {Y}_{i}^{T} )}{t}} , ∇ U ( {Y}_{i} ) = U ( {Y}_{i} ) \cdot ( - \frac{2}{t} \cdot \tilde{X} \cdot L \cdot {Y}_{i}^{T} ) ;$$
as such, the iteration is formulated as follows:
∇P(Yᵢ)=a·∇K(Yᵢ)+b·∇F(Yᵢ)+c·∇U(Yᵢ),
for the iteration, wᵢ is initialized with wᵢ⁰=(Yᵢ⁰−\tilde{X}⁻¹)^{T}, and \tilde{X}⁻¹ represents an inverse of \tilde{X}; the value of wᵢ after q iteration is: wᵢ^{q}=wᵢ^{q-1}+μ·dᵢ^{q-1}; wherein,
$${d}_{i} = \frac{∇ P ( {Y}_{i} )}{‖ ∇ P ( {Y}_{i} ) ‖}$$
is the iteration direction; the iteration step μ is determined by backtracing line search; the iteration step μ is initially set to 1, and if a total objective function value increases after each iteration, μ remains value, otherwise, the iteration step μ is halved until objective function value increases; and
if ∥wᵢ^{q}−wᵢ^{q-1}∥<10⁻⁵ or q reaches the maximum iteration time, wᵢ^{*}=wᵢ^{q}, go to perform step 7; otherwise, the reference component Rᵢ is updated by using (wᵢ^{q})^{T}·\tilde{X} and then go to perform step 4 to step 5.

10. The group information guided smooth independent component analysis method for brain functional network analysis of claim 1, wherein the calculating time course of the FN for the individual subject at step 8 further comprises: calculating the time course (TC) corresponding to each component in the individual subject based on an estimated component Y and individual subject's data matrix X by formula: TC=E(X·Y⁻¹), wherein Y⁻¹ represents an inverse of Y and E(·) represents a mathematical expectation.

11. The group information guided smooth independent component analysis method for brain functional network analysis of claim 1, wherein the calculating FNs and related time courses for all subjects at step 9 further comprises calculating each FN and related time courses for each individual subject according to step 4 to step 8.

12. A computer device, comprising a processor and a memory, the memory storing a computer program, wherein the computer program is executable by the processor to implement the steps of the group information guided smooth independent component analysis method for brain functional network analysis of any one of claim 1.

13. The computer device of claim 12, wherein the pre-processing of fMRI data at step 1 further comprises: removing first few time points of fMRI data and performing slice timing correction, head motion correction, spatial normalization, and spatial smoothing.

14. The computer device of claim 12, wherein data representing of each subject's fMRI data at step 1 refers to converting four-dimensional fMRI data into the two-dimensional matrix, which is drawing a three-dimensional image corresponding to each time point extracted from original fMRI data within a brain mask into a row, and then concatenating row vectors along the temporal direction to obtain a matrix X (size: N×S), wherein N represents the number of time points and S represents the number of voxels.

15. The computer device of claim 12, wherein the performing of PCA-based dimension reduction on the two-dimensional matrix data at both the subject level and the group level in sequence along the temporal direction at step 2 further comprises: performing PCA-based dimension reduction on the matrix X of each subject to achieve a dimension-reduced matrix (size: n1×S), wherein n1<N, then concatenating the dimension-reduced matrices of all subjects along the temporal dimension, and performing PCA-based dimension reduction on the concatenated data to further obtain a dimension-reduced matrix (size: n2×S), wherein, n2 is the number of components, and n1 is either equal to or greater than n2.

16. The computer device of claim 12, wherein at step 3, the FastICA algorithm or Infomax algorithm is applied for the ICA to obtain group-level components that are used for the initialization of reference components (Rᵢ, i=1, 2, . . . , n2).

17. The computer device of claim 12, wherein 13 voxel-level features calculated based on each reference component at step 4 comprise four types of features, comprising:
a first type of voxel-level features comprises activation state of each voxel in cerebrospinal fluid, an average activation state of neighbor voxels of each voxel in cerebrospinal fluid, and a mean similarity of activation states between a voxel and neighbor voxels thereof in cerebrospinal fluid;
a second type of voxel-level features comprises activation state of each voxel in white matter, an average activation state of neighbor voxels of each voxel in white matter, and a mean similarity of activation states between a voxel and neighbor voxels thereof in white matter;
a third type of voxel-level features comprises activation state of each voxel in brain edge, an average activation state of neighbor voxels of each voxel in brain edge, and a mean similarity of activation states between a voxel and neighbor voxels thereof in brain edge; and
a fourth type of voxel-level features comprises a size of connected region of each voxel, a voxel degree of each voxel, an average voxel degree of neighbor voxels of each voxel, and a mean similarity of voxel degrees between a voxel and neighbor voxels thereof; and
calculating the activation state of i-th voxel in cerebrospinal fluid, white matter, or brain edge comprises: Active_WMᵢ=WMmask(i), Active_CSFᵢ=CSFmask(i), and Active_BEᵢ=BEmask(i); WMmask(·), CSFmask(·), and BEmask(·) denote that if a voxel is activated in the white matter mask, cerebrospinal fluid mask, or brain edge mask, the feature value is set to 1; otherwise, the feature value is set to 0;
calculating the average activation state of neighbor voxels of i-th voxel in cerebrospinal fluid, white matter, or brain edge comprises:
$$Active {Mean\_WM}_{i} = \frac{{\sum }_{j}^{j ϵ {neigh}_{i}} {Active\_WM}_{j}}{{neigh\_len}_{i}} ,$$
$$Active {Mean\_CSF}_{i} = \frac{{\sum }_{j}^{j ϵ {neigh}_{i}} {Active\_CSF}_{j}}{{neigh\_len}_{i}} , and$$
$$Active {Raito\_BE}_{i} = \frac{{\sum }_{j}^{j ϵ {neigh}_{i}} {Active\_BE}_{j}}{{neigh\_len}_{i}} ;$$
wherein, the neighᵢ represents the spatially neighbor voxels of the i-th voxel, and the neigh_lenᵢ represents the number of neighbor voxels of the i-th voxel;
calculating the mean similarity of activation states between a voxel and neighbor voxels thereof in cerebrospinal fluid, white matter, or brain edge comprises: the similarity between activation states of i-th voxel and j-th voxel in white matter is:
$${Corr\_WM}_{i , j} = \{ \begin{matrix}1 & if {Active\_WM}_{i} = {Active\_WM}_{j} \\ 0 & Otherwise\end{matrix}$$
the mean similarity of activation states between the i-th voxel and neighbor voxels thereof in white matter is
$$Corr {Mean\_WM}_{i} = \frac{{\sum }_{j}^{j ϵ {neigh}_{i}} {Corr\_WM}_{i , j}}{{neigh\_len}_{i}} ;$$
the mean similarity of activation states between the i-th voxel and neighbor voxels thereof in cerebrospinal fluid and brain edge are
$$Corr {Mean\_CSF}_{i} = \frac{{\sum }_{j}^{j ϵ {neigh}_{i}} {Corr\_CSF}_{i , j}}{{neigh\_len}_{i}} , and$$
$$Corr {Mean\_BE}_{i} = \frac{{\sum }_{j}^{j ϵ {neigh}_{i}} {Corr\_BE}_{i , j}}{{neigh\_len}_{i}} ,$$
respectively;
calculating the voxel degree of i-th voxel comprises:
$${Voxel\_degree}_{i} = {\sum }_{j}^{j ϵ {neigh}_{i}} \frac{1}{\vert {Z}_{i} - {Z}_{j} \vert} ;$$
wherein, Zᵢ and Zⱼ represent the corresponding z-score of the i-th voxel and the j-th voxel in a component;
calculating the average voxel degree of neighbor voxels of the i-th voxel comprises:
$${Degree\_Mean}_{i} = \frac{{\sum }_{j}^{j ϵ {neigh}_{i}} {Voxel\_degree}_{j}}{{neigh\_len}_{i}} ;$$
calculating the mean similarity of voxel degrees between the i-th voxel and neighbor voxels thereof comprises:
$$Corr {Mean\_degree}_{i , j} = \frac{{\sum }_{j}^{j ϵ {neigh}_{i}} \frac{1}{{e}^{{Voxel\_degree}_{i} - {Voxel\_degree}_{j}}}}{{neigh\_len}_{i}} ;$$
and
calculating the size of connected region of each voxel comprises: aggregating a voxel into a region by a region growing algorithm, and the region growing is based on Z-scores of voxels in component, finally taking the voxel number of the region as a feature value.

18. The computer device of claim 12, wherein during the construction of the multi-objective function by employing the voxel-level features of each component, each reference component, and the individual subject's data matrix at step 5, the multi-objective function is as follows:
$$max \{ \begin{matrix}J ( {Y}_{i} ) = {\{ E [ G ( {Y}_{i} ) ] - E [ G ( v ) ] \}}^{2} \\ F ( {Y}_{i} ) = E ( {Y}_{i} \cdot {R}_{i} ) \\ T ( {Y}_{i} ) = - Tr ( {Y}_{i} \cdot L \cdot {Y}_{i}^{T} )\end{matrix} ,$$
an optimization target of the multi-objective function comprises independence of each component, correspondence between each component and related reference component Rᵢ, and smoothness of each component; wherein, J(Yᵢ) is a negative entropy of an estimated independent component Yᵢ=wᵢ^{T}·\tilde{X}, which is used to reflect the independence of the component; wᵢ (size: N×1) represents associated unmixing vector; \tilde{X} represents a whitened X; v represents a Gaussian variable with zero mean and unit variance; G(·) represents any non-quadratic function, and E(·) represents the mathematical expectation; F(Yᵢ) is used to represent the correspondence between Yᵢ and Rᵢ to ensure comparability of components across subjects; T(Yᵢ) refers to a graph regularization term computed by using 13 voxel-level features; Tr(·) represents a trace of the matrix; L=D−Q represents a Laplace matrix, wherein D represents a degree matrix, and Q computed based on voxel-level features represents similarity between voxels in the component;
regarding Q, an adjacency matrix is calculated to reflect the between-voxel similarity based on each type of voxel-level features, yielding Q₁, Q₂, Q₃, and Q₄, and then each Qᵢ (i=1, 2, 3, 4) is taken independently as Q for removing specific noises or jointly to generate Q (Q=Q₁+Q₂+Q₃+Q₄) for removing all types of noises; to compute each Qᵢ (i=1, 2, 3, 4), first the voxel-level features within the same type are multiplied together to obtain VoxF_i (size: S×1); then a sparse distance matrix WF is calculated based on space information of voxels and finally Qᵢ=WF·VoxF_i·VoxF_i^{T} is calculated; and
regarding the degree matrix D, values of diagonal elements of D are column sums of corresponding adjacency matrix Q.

19. The computer device of claim 18, wherein the normalizing of the multi-objective function at step 5 further comprises: normalizing the multi-objective function by an inverse tangent function and an exponential function with base e;
the normalized multi-objective function is denoted as:
$$max \{ \begin{matrix}K ( {Y}_{i} ) = \frac{2}{π} \cdot arc tan ( z \cdot {\{ E [ G ( {Y}_{i} ) ] - E [ G ( v ) ] \}}^{2} ) \\ F ( {Y}_{i} ) = E ( {Y}_{i} \cdot {R}_{i} ) \\ U ( {Y}_{i} ) = {e}^{\frac{- T r ( {Y}_{i} \cdot L \cdot {Y}_{i}^{T} )}{t}}\end{matrix} ,$$
$$z = tan ( F ( {Y}_{i}^{0} ) \cdot \frac{π}{2} ) / {\{ E [ G ( {Y}_{i}^{0} ) ] - E [ G ( v ) ] \}}^{2} , t = - Tr ( {Y}_{i}^{0} \cdot L \cdot {Y}_{i}^{{0}^{T}} ) / ln ( F ( {Y}_{i}^{0} ) ) ,$$
wherein, Yᵢ⁰ denotes initial Yᵢ and is i-th group-level IC.

20. A computer-readable storage medium having stored a computer program, wherein the computer program is executable by a processor to implement the steps of the group information guided smooth independent component analysis method for brain functional network analysis of claim 1.
